(19) United States
(12) Patent Application Publication
(10) Pub. No.: US 2021/0222858 A1
(43) Pub. Date: Jul. 22, 2021

(54) Self-Aligning And Anti-Rotating Fastening Devices For Circuit Boards

(71) Applicant: SIGNIFY HOLDING B.V., EINDHOVEN (NL)

(72) Inventors: Vikas Bhurangi, Pune (IN); Devanand Ramchandra Gole, Pune (IN); Venkatesh Pulimamidi, Kurnool (IN); Pooja Saraswat, Mathura (IN); Pushkar Chaudhari, Pune (IN); Sridhar Reddy Nimma, Cumming, GA (US)

(21) Appl. No.: 16/746,605

(22) Filed: Jan. 17, 2020

(51) Int. Cl. F21V 19/00; F21V 15/01; H05K 1/18; F16B 5/06

(52) U.S. Cl. CPC F21V 19/005; F21V 15/01; H05K 1/181; F21Y 2115/10; H05K 2201/10106; H05K 2201/10522; F16B 5/06

(57) ABSTRACT

A fastening device for a circuit board of an electrical device can include a body having a first portion and a second portion, where the body has an aperture that traverses therethrough. The fastening device can also include a first protruding section disposed on a bottom surface of the body adjacent to the aperture. The first protruding section can be configured to abut against a top surface of an enclosure wall of the electrical device and a side of the circuit board. The aperture can be configured to receive a coupling device of the electrical device. The first portion of the body is configured to abut against a top surface of the circuit board when the aperture receives the coupling device of the electrical device.

### TECHNICAL FIELD

Embodiments described herein relate generally to circuit boards, and more particularly to systems, methods, and devices for securing circuit boards within an enclosure.

### BACKGROUND

Circuit boards are used in a wide variety of applications. In many cases, a circuit board is secured within an enclosure, such as a housing for a light fixture. Securing a circuit board within an enclosure can be a time-consuming process that can also require additional parts and/or other materials. Thus, securing a circuit board to an enclosure, while necessary for a device to function properly, adds to the cost of that device.

### SUMMARY

In general, in one aspect, the disclosure relates to a fastening device for a circuit board of an electrical device. The fastening device can include a body having a first portion and a second portion, where the body has an aperture that traverses threrethrough. The fastening device can also include a first protruding section disposed on a bottom surface of the body adjacent to the aperture. The first protruding section can be configured to abut against a top surface of an enclosure wall of the electrical device and a side of the circuit board. The aperture can be configured to receive a coupling device of the electrical device. The first portion of the body can be configured to abut against a top surface of the circuit board when the aperture receives the coupling device of the electrical device.

In another aspect, the disclosure can generally relate to an electrical device that includes an enclosure, a circuit board, a first fastening device, and a first coupling device. The enclosure can include at least one wall having an inner surface and a first circuit board coupling feature disposed in the inner surface of the at least one wall, where the first circuit board coupling feature includes a first aperture that traverses the at least one wall. The circuit board can be disposed against the inner surface of the at least one wall of the enclosure. The first fastening device can include a body having a first portion and a second portion, where the body has a second aperture that traverses therethrough. The first fastening device can also include a first protruding section disposed on a bottom surface of the body adjacent to the second aperture. The first coupling device can be disposed within the first aperture and the second aperture to secure the first fastening device to the at least one wall of the enclosure. The first protruding section can abut against the top surface of the at least one wall of the enclosure and a side of the circuit board. The first portion of the body can abut against a top surface of the circuit board when the first aperture and the second aperture receive the first coupling device.

These and other aspects, objects, features, and embodiments will be apparent from the following description and the appended claims.

### BRIEF DESCRIPTION OF THE DRAWINGS

The drawings illustrate only example embodiments of self-aligning and anti-rotating fastening devices for circuit boards and are therefore not to be considered limiting of its scope, as self-aligning and anti-rotating fastening devices for circuit boards may admit to other equally effective embodiments. The elements and features shown in the drawings are not necessarily to scale, emphasis instead being placed upon clearly illustrating the principles of the example embodiments. Additionally, certain dimensions or positionings may be exaggerated to help visually convey such principles. In the drawings, reference numerals designate like or corresponding, but not necessarily identical, elements.

FIG. 1 shows a circuit board in accordance with the current art.

FIG. 2 shows a wall of an enclosure in accordance with the current art.

FIGS. 3 and 4 show examples of an electrical device with a circuit board coupling to an enclosure wall in accordance with the current art.

FIGS. 5A through 5D show various views of a fastening device in accordance with certain example embodiments.

FIG. 6 shows a cross-sectional side view of a portion of an electrical device that includes a fastening device in accordance with certain example embodiments.

FIGS. 7A and 7B show a portion of another electrical device that includes multiple fastening devices in accordance with certain example embodiments.

FIGS. 8A and 8B show various views of another fastening device in accordance with certain example embodiments.

### DETAILED DESCRIPTION OF EXAMPLE EMBODIMENTS

The example embodiments discussed herein are directed to systems, methods, and devices for self-aligning and anti-rotating fastening devices for circuit boards. While example embodiments are directed herein to circuit boards that couple to walls of an enclosure, example circuit boards can be coupled to any other type of surface to which a circuit board can be mounted. An enclosure can be any type of enclosure used in any type of application. Examples of an enclosure can include, but are not limited to, a light fixture housing, a control panel, a junction box, a housing for a computer (e.g., desktop, laptop, electronic pad), a casing for a smart phone, a housing for a television set, a housing for a monitor, a housing for an appliance (e.g., a dishwasher, a clothes washing machine, a housing for a microwave oven), an electrical connector housing, a motor control center, a breaker cabinet, a conduit, an indicating panel, and a control cabinet and a housing for a digital clock.

When an enclosure is a housing for a light fixture, the light fixture can be any type of luminaire, including but not limited to a linear light fixture, a pendant light fixture, an emergency egress light fixture, a floodlight, and a troffer light fixture. Example embodiments can be used in any of a variety of indoor and outdoor environments, including but not limited to sterile, high humidity, high temperature, low temperature, high vibration, hazardous, and corrosive. As used herein, a lighting fixture (e.g., a LED floodlight) (also sometimes called a light fixture or a luminaire) can be an entire fixture, a part of a fixture (e.g., a module among multiple modules of a fixture), or any other component of a fixture.

In one or more example embodiments, an enclosure in which an example circuit board is mounted is subject to meeting certain standards and/or requirements set by one or more of a number of authorities. Examples of such authorities include, but are not limited to, the National Electric Code (NEC), the Canadian Electric Code (CEC), the International Electrotechnical Commission (IEC), the National Electrical Manufacturers Association (NEMA), Underwriter's Laboratories (UL), the Standards Council of Canada, Conformité Européenne (CE), and the Appareils destinés à être utilisés en Atmosphères Explosives (ATEX). The example embodiments described herein can allow each enclosure to continue to meet such standards and/or regulations.

The example fastening devices (or components thereof) described herein can be made of one or more of a number of suitable materials to allow the circuit boards (or enclosure in which the circuit boards are mounted) to meet certain standards and/or regulations while also maintaining durability in light of the one or more conditions under which the circuit boards can be exposed. Examples of such materials can include, but are not limited to, aluminum, stainless steel, fiberglass, plastic (e.g., nylon), ceramic, and rubber. Example fastening devices can be used as part of a new electrical device. In addition, or in the alternative, example fastening devices can be used with existing electrical devices (and components thereof).

A circuit board that is secured by the example fastening devices can have one or more of any of a number of components disposed thereon. Examples of such components can include, but are not limited to, an integrated circuit, a light source, a light engine, a resistor, a capacitor, a terminal block, and an electrical lead. If the circuit board includes a light source, the light source can be any of a number of different types of light sources. Examples of a light source can include, but are not limited to, light-emitting diodes (LEDs) and organic LEDs (OLEDs). The LED light sources described herein may include any type of LED technology, including, but not limited to, chip on board and discrete die.

A user may be any person that interacts with an enclosure that houses one or more circuit boards that are secured to the enclosure using example embodiments described herein. Specifically, a user may install, maintain, operate, and/or interface with a circuit board and/or enclosure in which a circuit board is mounted. Examples of a user may include, but are not limited to, an engineer, an electrician, an instrumentation and controls technician, a mechanic, an operator, a consultant, a contractor, and a manufacturer's representative.

Example fastening devices described herein can be made from a single piece (as from a mold, injection mold, die cast, or extrusion process). In addition, or in the alternative, example embodiments of fastening devices can be made from multiple pieces that are mechanically coupled to each other. In such a case, the multiple pieces can be mechanically coupled to each other using one or more of a number of coupling methods, including but not limited to epoxy, welding, fastening devices, compression fittings, mating threads, and slotted fittings. One or more pieces that are mechanically coupled to each other can be coupled to each other in one or more of a number of ways, including but not limited to fixedly, hingedly, removeably, slidably, and threadably.

Components and/or features described herein can include elements that are described as coupling, fastening, securing, abutting, or other similar terms. Such terms are merely meant to distinguish various elements and/or features within a component or device and are not meant to limit the capability or function of that particular element and/or feature. For example, a feature described as a “coupling feature” can couple, secure, fasten, abut, and/or perform other functions aside from, or in addition to, merely coupling.

A coupling feature (including a complementary coupling feature) as described herein can allow one or more components (e.g., a circuit board) and/or portions thereof to become mechanically coupled, directly or indirectly, to a wall of an enclosure. A coupling feature can include, but is not limited to, an example fastening device, a clamp, a portion of a hinge, an aperture, a recessed area, a protrusion, a slot, a spring clip, a tab, a detent, a threaded coupling, and mating threads. One or more portions of a circuit board can be coupled to a wall of an enclosure by the direct or indirect use of one or more fastening devices, which each use one or more coupling features. In addition, in some cases, one or more other portions of an example circuit board can be coupled to a wall of an enclosure using one or more other independent devices that interact with one or more coupling features disposed on a component of the circuit board and/or enclosure. Examples of such other independent devices can include, but are not limited to, a pin, a hinge, a fastening device (e.g., a bolt, a screw, a rivet), and a spring.

One coupling feature described herein can be the same as, or different than, one or more other coupling features described herein. A complementary coupling feature as described herein can be a coupling feature that mechanically couples, directly or indirectly, with another coupling feature. For any figure shown and described herein, one or more of the components may be omitted, added, repeated, and/or substituted. Accordingly, embodiments shown in a particular figure should not be considered limited to the specific arrangements of components shown in such figure. For example, features shown in one or more figures or described with respect to one embodiment can be applied to another embodiment associated with a different figure or description.

Further, if a component of a figure is described but not expressly shown or labeled in that figure, the label used for a corresponding component in another figure can be inferred to that component. Conversely, if a component in a figure is labeled but not described, the description for such component can be substantially the same as the description for the corresponding component in another figure. The numbering scheme for the various components in the figures herein is such that each component is a three digit number and corresponding components in other figures have the identical last two digits.

Example embodiments will be described more fully hereinafter with reference to the accompanying drawings, in which example embodiments are shown. Example embodiments may, however, be embodied in many different forms and should not be construed as limited to those set forth herein. Rather, these example embodiments are provided so that this disclosure will be thorough and complete, and will fully convey the scope of slide locks for circuit boards to those or ordinary skill in the art. Like, but not necessarily the same, elements (also sometimes called components or features) in the various figures are denoted by like reference numerals for consistency.

Terms such as “first”, “second”, “side”, “top”, “bottom”, “distal”, “open”, “closed”, and “within” are used merely to distinguish one component (or part of a component or state of a component) from another. Such terms are not meant to denote a preference or a particular orientation. Such terms are not meant to limit example embodiments. In the following detailed description of the example embodiments, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

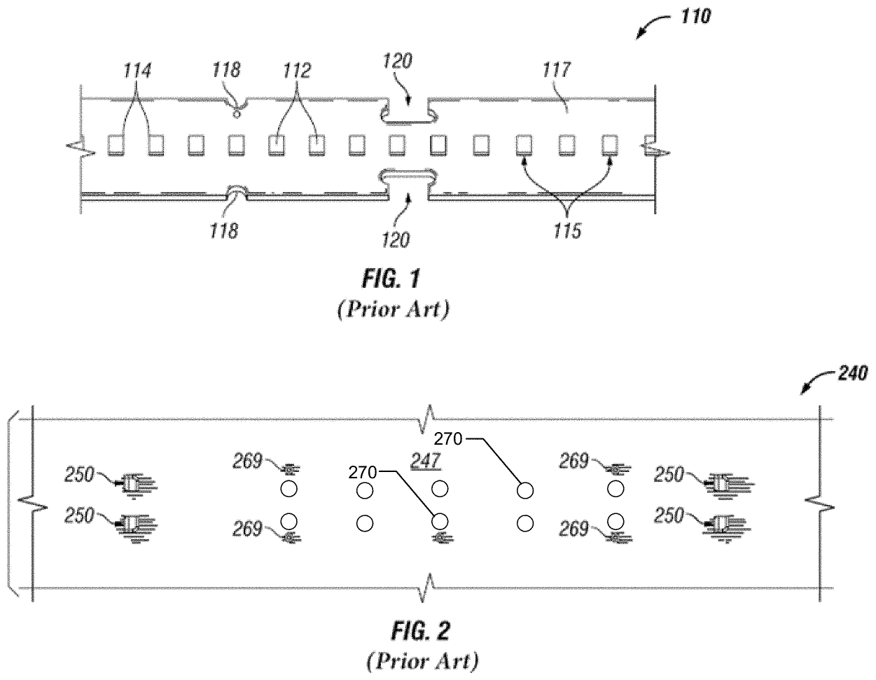

FIG. 1 shows a top view of a circuit board 110 in accordance with the current art. The circuit board 110 is a medium that includes, and on which are disposed, one or more of a number of discrete components (e.g., capacitor, power terminal, power terminal, resistor, light assembly 115) and/or one or more integrated circuits that are interconnected with each other by a number of wire traces embedded in the circuit board 110. The circuit board 110 can be called one or more of a number of other names, including but not limited to a board, a wiring board, a printed wiring board, a PWB, a printed circuit board, and a PCB.

As shown in FIG. 1, the circuit board 110 includes multiple light assemblies 115. In this case, the light assemblies 115 are disposed on a top surface of the body 117 of the circuit board 110. The components and/or configuration of each light assembly 115 can vary. For example, as shown in FIG. 1, each light assembly 115 can include one or more light sources 112 mounted on one or more light source receivers 114. When the circuit board 110 has multiple light assemblies 115, as shown in FIGS. 1A and 1B, the light assemblies 115 can be arranged in one or more of a number of arrays or other configurations. In this case, the light assemblies 115 are linearly aligned with each other. Control and/or power signals (e.g., voltage, current) are directly or indirectly delivered to the circuit board 110 by a power source (e.g., a LED driver) (not shown) located within, on, and/or external to the enclosure. Such power and/or control signals can be used to illuminate the light assemblies 115 of the circuit board 110.

The light assemblies 115 can be electrically coupled to each other. For example, the light assemblies 115 can be series-connected in some way (e.g., row-to-row serpentine, column-to-column serpentine). Further, one or more light assemblies 115 in one array can be electrically coupled to one or more light assemblies 115 in another (e.g., an adjacent) array so that a single feed of power to a circuit board 110 can provide sufficient power to all light assemblies 115 disposed on the circuit board 110.

The circuit board 110 can include one or more of a number of coupling features that allow the circuit board 110 to mechanically couple to one or more portions (e.g., a wall) of an enclosure. For example, as shown in FIG. 1, the circuit board 110 can include a number of enclosure coupling features 120 that are in the form of oblong notches. In this case, the enclosure coupling features 120 are formed in pairs on either side of the body 117 of the circuit board 110. This symmetric configuration of enclosure coupling features 120 along the length of the body 117 of the circuit board 110 can be replaced by other configurations, such as a single enclosure coupling feature 120 or a random placement of enclosure coupling features 120 along one or more outer sides 129 of the body 117 of the circuit board 110.

An enclosure coupling feature 120 can have one or more of a number of configurations. Such configurations are designed to complement corresponding circuit board coupling features of the enclosure to allow the circuit board 110 to become affixed to the enclosure in a certain position relative to the enclosure. An example of circuit board coupling features that complement the enclosure coupling features 120 are described below and shown in FIG. 2. In some cases, the enclosure coupling features 120 are optional for the circuit board 110.

In certain example embodiments, the circuit board 110 can include one or more other coupling features. For example, as shown in FIG. 1, there can be one or more enclosure coupling features 118 disposed in the body 117 of the circuit board 110. The enclosure coupling features 118 can have a different configuration when compared with the enclosure coupling features 120 described above. In this particular case, the enclosure coupling features 118 are apertures that traverse the body 117 of the circuit board 110.

The enclosure coupling features 118 can be disposed at any location along the body 117 of the circuit board 110. In this example, the enclosure coupling features 118 are disposed along the outer edge of the body 117 of the circuit board 110. As such, the enclosure coupling features 118 are semi-circular in shape and sized substantially similar to a fastening device (e.g., a screw, a bolt) that can be disposed therein. The enclosure coupling features 118 can have any of a number of other shapes and/or sizes. Each enclosure coupling feature 118 is configured to couple to, directly or indirectly, with a corresponding circuit board coupling feature of an enclosure, as described below and shown in FIG. 2.

Since the enclosure coupling features 118 and the optional enclosure coupling features 120 can incur more mechanical stress compared to other parts of the circuit board 110, the enclosure coupling features 118 and the enclosure coupling features 120 can be disposed on a different portion of the body 117 compared to the parts of the body 117 on which the other components (e.g., light assemblies 115) of the circuit board 110 are disposed. Such a portion of the body 117 can have higher mechanical strength, have different thermal properties, and/or have one or more other characteristics that are different compared to those of the rest of the body 117.

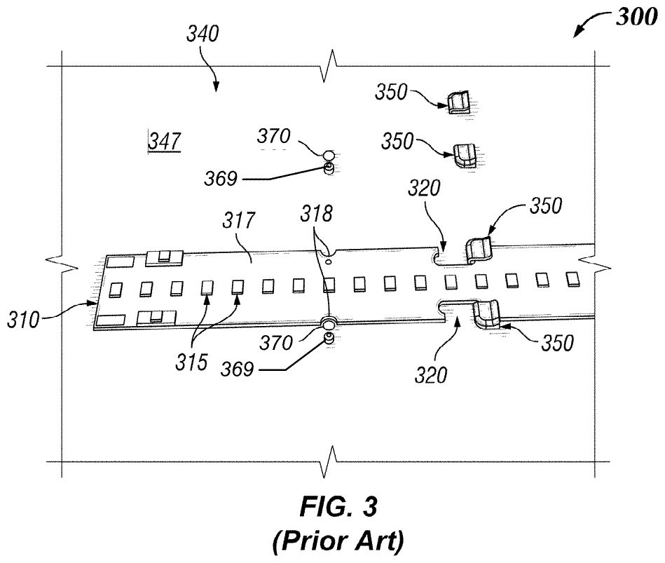

In some cases, as shown in FIG. 3 below, an enclosure coupling feature 118 is only able to couple to a corresponding circuit board coupling feature of an enclosure when the circuit board 110 is aligned in a certain way relative to the wall of the enclosure. For example, an enclosure coupling feature 118 is only able to couple to a corresponding circuit board coupling feature of an enclosure when an enclosure coupling feature 120 is coupled to a corresponding circuit board coupling feature (e.g., circuit board coupling feature 250 of FIG. 2) of the enclosure.

In certain example embodiments, where the enclosure coupling features 118 and/or the enclosure coupling features 120 are apertures, such enclosure coupling features 118 and/or the enclosure coupling features 120 can be cut, stamped, drilled, and/or otherwise formed within the body 117 (or portion thereof) of the circuit board 110 so that the circuit board 110 is a single piece (or collection of pieces) relative to the enclosure coupling features 118 and/or the enclosure coupling features 120.

FIG. 2 shows a top view of a portion of a wall 247 of an enclosure 240 in accordance with the current art. Referring to FIGS. 1 and 2, the wall 247 of the enclosure 240 can be directly exposed to a circuit board (e.g., circuit board 110). The enclosure 240 (also called an electrical enclosure 240 herein) can be any type of cabinet or housing inside of which is disposed one or more of a number of different electrical devices. Such electrical devices can include, but are not limited to, circuit boards (e.g., circuit board 110), variable frequency drives (VFDs), controllers, relay coils, contactors, transformers, inverters, converters, fuses, electrical cables, sensor devices, and electrical conductors. An electrical enclosure 240 can be completely enclosed, partially enclosed, partially open, or completely open. An electrical enclosure 240 can have one or more covers that are removable, allowing access to an interior of the electrical enclosure 240.

The wall 247 of the enclosure 240 can include one or more of a number of circuit board coupling features that allow a circuit board (e.g., circuit board 110) to mechanically couple, directly or indirectly, to one or more portions of the wall 247 of the enclosure 240. For example, as shown in FIG. 2, the wall 247 can include a number of circuit board coupling features 250, circuit board coupling features 269, and circuit board coupling features 270. In this case, the circuit board coupling features 250 and the circuit board coupling features 270 are formed in pairs along various portions of the wall 247 of the enclosure 240. In some cases, a circuit board coupling feature 269 accompanies (is disposed adjacent to) a circuit board coupling feature 270.

This configuration of circuit board coupling features 250 is designed to correspond to the configuration of one or more enclosure coupling features (e.g., enclosure coupling features 120) of a circuit board (e.g., circuit board 110) that are coupled to and disposed within the enclosure 240. Similarly, this configuration of circuit board coupling features 269 and circuit board coupling features 270 is designed to correspond to the configuration of one or more other enclosure coupling features (e.g., enclosure coupling features 118) of a circuit board (e.g., circuit board 110) that are coupled to and disposed within the enclosure 240.

The configuration of circuit board coupling features 250, circuit board coupling features 269, and circuit board coupling features 270 shown in FIG. 2 can be replaced by other configurations, such as a single circuit board coupling feature 270 or a random placement of circuit board coupling features 270 along the wall 247 of the enclosure 240. In some cases, a circuit board coupling feature 270 and an adjacent circuit board coupling feature 269 can collectively be considered as a single circuit board coupling feature with multiple components. In this way, circuit board coupling feature 269 can be considered an optional component of the overall circuit board coupling feature that also includes circuit board coupling feature 270.

In this case, each of the circuit board coupling features 250 is a protrusion with at least two open sides. Also, each of the circuit board coupling features 270 is an aperture in the wall 247. Further, each of the circuit board coupling features 269 is a dimple in the wall that extends outward. As described herein, the wall 247 can be an actual wall of the enclosure 240. Alternatively, the wall 247 can be a plate that is mounted to another wall of the enclosure 240.

The circuit board coupling features 269 can be sized substantially similar to a coupling device (e.g., a screw, a bolt) that can be disposed therein. The circuit board coupling features 269 can have any of a number of other shapes and/or sizes. Each circuit board coupling features 269 is configured to couple to, directly or indirectly, with a corresponding enclosure coupling feature (e.g., enclosure coupling feature 118) of a circuit board.

In some cases, as shown in FIG. 3 below, a circuit board coupling feature (e.g., circuit board coupling feature 269, circuit board coupling feature 270) is only able to couple to a corresponding enclosure coupling feature of a circuit board when the circuit board 110 is aligned in a certain way relative to the wall 247 of the enclosure 240. For example, a circuit board coupling features 270 is only able to couple to a corresponding enclosure coupling feature 118 of a circuit board 100 when the enclosure coupling feature 118 is coupled to a corresponding circuit board coupling feature 270 of the enclosure 240.

In certain example embodiments, where the circuit board coupling features 269 and/or the circuit board coupling features 270 are dimples and apertures, respectively, such circuit board coupling features 269 and/or the circuit board coupling features 270 can be cut, stamped, extruded, drilled, and/or otherwise formed within the wall 247 (or other portion) of the enclosure 240 so that the wall 247 is a single piece (or collection of pieces) relative to the circuit board coupling features 269 and/or the circuit board coupling features 270.

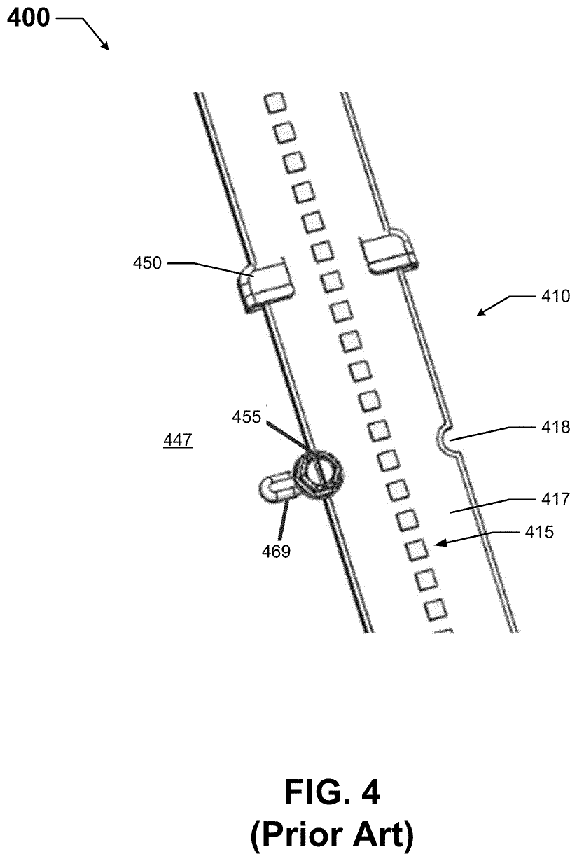

FIGS. 3 and 4 each show an example of an electrical device in accordance with the current art. Specifically, FIG. 3 shows a portion of the electrical device 300 in which a circuit board 310 is coupled to a wall 347 of an enclosure 340. FIG. 4 shows a portion of another electrical device in which the circuit board 310 is coupled to the wall 447 of an enclosure.

Referring to FIGS. 1 through 4, the electrical device 300 of FIG. 3 includes a circuit board 310 that is substantially the same as the circuit board 110 of FIG. 1. Specifically, the circuit board 310 includes two enclosure coupling features 320 (in the form of oblong notches) that are aligned with each other along an outer edge of the body 317. The circuit board 310 also includes two other enclosure coupling features 318 (in the form of semi-circular apertures) that are aligned with each other along an outer edge of the body 317. The circuit board 310 further includes a number of light assemblies 315 disposed on a top surface of the body 317 of the circuit board 310.

In addition, the electrical device of FIG. 3 includes an enclosure 340 that is substantially the same as the enclosure 240 of FIG. 2. Specifically, the wall 347 of the enclosure 340 of FIG. 3 includes two circuit board coupling features 350 that are arranged to align with the two enclosure coupling features 320 of the circuit board 310. The wall 347 of the enclosure 340 of FIG. 3 also includes two other circuit board coupling features 369 (in the form of dimples in the wall 347 of the enclosure 340) and two adjacent circuit board coupling features 370 (in the form of apertures in the wall 347 of the enclosure 340) that are arranged to align with the two enclosure coupling features 318 of the circuit board 310.

In FIG. 3, the circuit board 310 is placed against the wall 347 of the enclosure 340 so that each of the circuit board coupling features 350 of the enclosure 340 is aligned with and couples to the corresponding enclosure coupling features 320 of the circuit board. Coincidentally, as shown in FIG. 3, one of the circuit board coupling features 370 of the enclosure 340 and one of the enclosure coupling features 318 of the circuit board 310 are aligned with each other. As a result, the circuit board coupling feature 370 and the enclosure coupling feature 318 of the electrical device 300 of FIG. 3 can be coupled to each other using an independent coupling device.

In FIG. 4, the electrical device 400 is substantially the same as the electrical device 300 of FIG. 3, except that an independent coupling device 455 is used to couple the circuit board 410 to the wall 447 of the enclosure. For example, the circuit board 410 of FIG. 4 includes two enclosure coupling features (in the form of oblong notches) (hidden from view by circuit board coupling features 450, but substantially similar to circuit board coupling features 320 discussed above) that are aligned with each other along an outer edge of the body 417. The circuit board 410 also includes two other enclosure coupling features 418 (in the form of semi-circular apertures) (one of which is hidden from view by coupling device 455) that are aligned with each other along an outer edge of the body 417. The circuit board 410 further includes a number of light assemblies 415 disposed on a top surface of the body 417 of the circuit board 410.

Also, the wall 447 of the enclosure includes two circuit board coupling features 450 that are arranged to align with the two enclosure coupling features hidden from view) of the circuit board 410. The wall 447 of the enclosure of FIG. 4 also includes one circuit board coupling feature (hidden from view) (in the form of an aperture in the wall 447 of the enclosure 440, similar to circuit board coupling features 370 of FIG. 3) that is arranged to align with one of the enclosure coupling features 418 of the circuit board 410. FIG. 4 also shows one circuit board coupling feature 469 (in the form of a dimple in the wall 447 of the enclosure) that is adjacent to the coupling device 455 disposed within the circuit board coupling feature.

The coupling device 455 in this case is a screw that is designed to couple the circuit board 410 to the wall 447 of the enclosure. However, events (e.g., vibration, fluctuations between hot and cold) over time, both within the enclosure and in the ambient environment in which the enclosure is located, can cause the coupling device 455 to loosen over time. When this occurs, the circuit board 410 can move or shift. When this occurs, even in minute amounts in some cases, misoperation or failure of the corresponding electrical device can result. Use of example fastening devices can extend the amount of time that such misoperations or failures can be avoided.

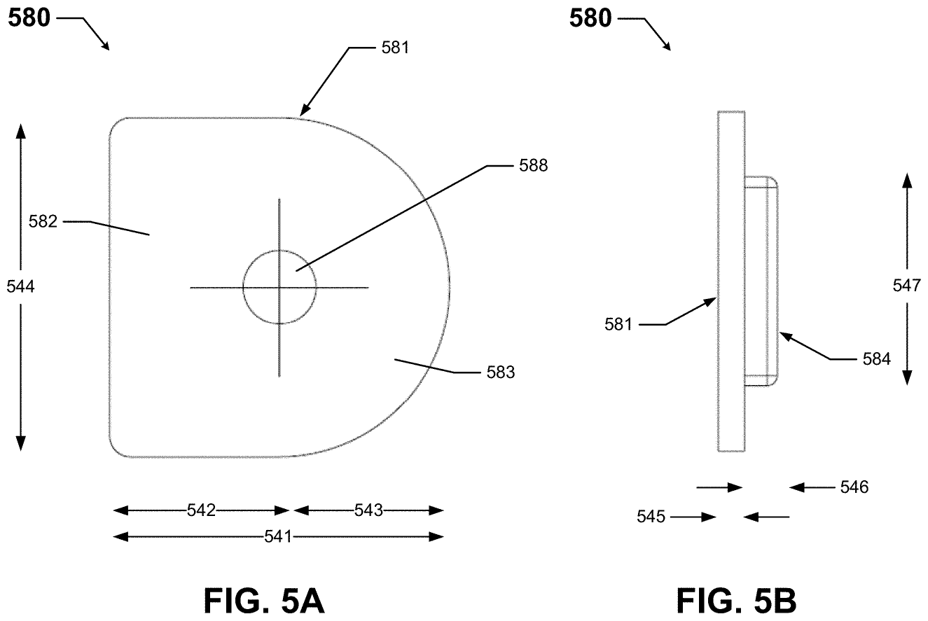

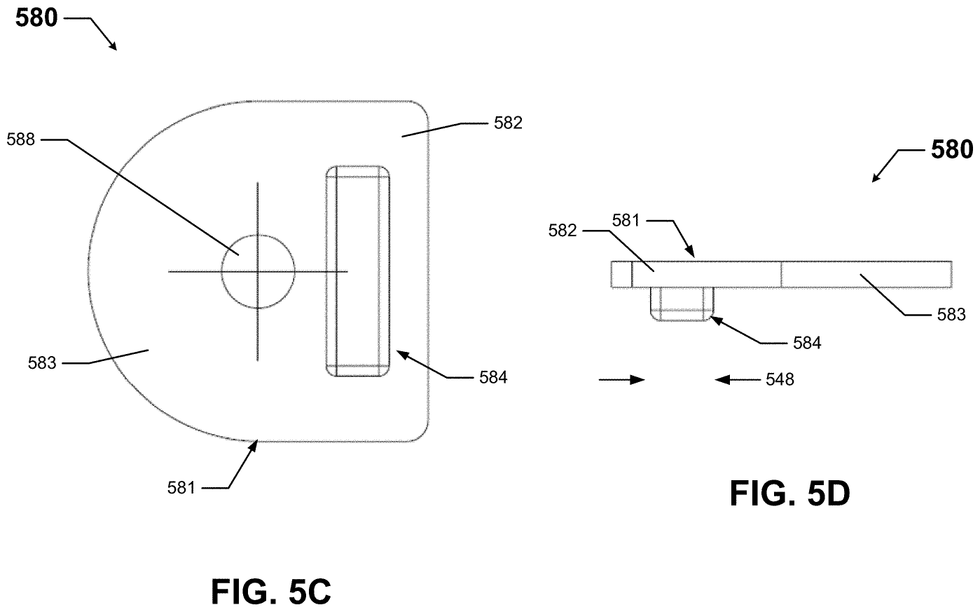

FIGS. 5A through 5D show various views of a fastening device 580 in accordance with certain example embodiments. Specifically, FIG. 5A shows a top view of the fastening device 580. FIG. 5B shows an end view of the fastening device 580. FIG. 5C shows a bottom view of the fastening device 580. FIG. 5D shows a side view of the fastening device 580. The example fastening device 580 shown in FIGS. 5A through 5D is not meant to be an exclusive embodiment.

Referring to FIGS. 1 through 5D, the example fastening device 580 includes a number of features and portions. For example, the fastening device 580 includes a body 581 that has several portions. In this case, the body 581 has portion 582 and portion 583. Portions 582 and 583 of the body 581 in this case are continuous and planar with respect to each other. In alternative embodiments portions 582 and portions 583 can be anti-planar with respect to each other.

Portion 582 of the body 581 has a length 542, a width 544, and a height 545. Similarly, portion 583 of the body 581 has a length 543, the width 544, and the height 545. In this example, portion 582 is substantially rectangular when viewed from above, and portion 583 is substantially semi-circular when viewed from above. In alternative embodiments, portion 582 and/or portion 583 can have any of a number of other shapes (e.g., triangular, sawtooth, random) when viewed from above.

An aperture 588 traverses the body 581. The aperture 588 in this case is circular and has a diameter that is substantially the same as a coupling device (e.g., coupling device 455) or a circuit board coupling feature (e.g., circuit board coupling feature 270). In alternative embodiments, the aperture 588 can have any of a number of other shapes. Also, while one aperture 588 traverses the body 581 in this case, multiple apertures can traverse the body 581 in alternative embodiments. In this example, the aperture 588 is approximately centered at the boundary between portion 582 and portion 583.

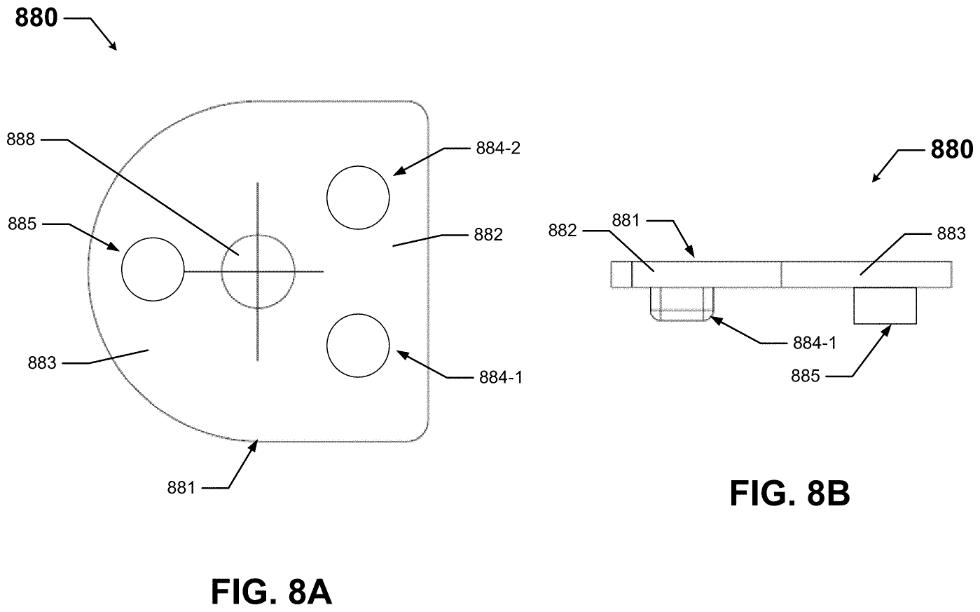

The example fastening device 580 of FIGS. 5A through 5D also includes a protruding section 584. In this case, the protruding section 584 is disposed on the bottom surface of portion 582 of the body 581, adjacent to the aperture 588. The protruding section 584 in this case is rectangular when viewed from below and has a length 547, a width 548, and a height 546. In alternative embodiments, the protruding section 584 can have any of a number of other shapes (e.g., circular, hexagonal) when viewed from below. Also, an example fastening device 580 can have multiple protruding sections. In addition, or in the alternative, a protruding section of the fastening device 580 can have multiple protrusions. Further, one or more protruding sections can be disposed on portion 583 of the body 581. In addition, portion 582 of the body 581 can have no protruding sections. An example showing some of these variations is provided below with respect to FIGS. 8A and 8B.

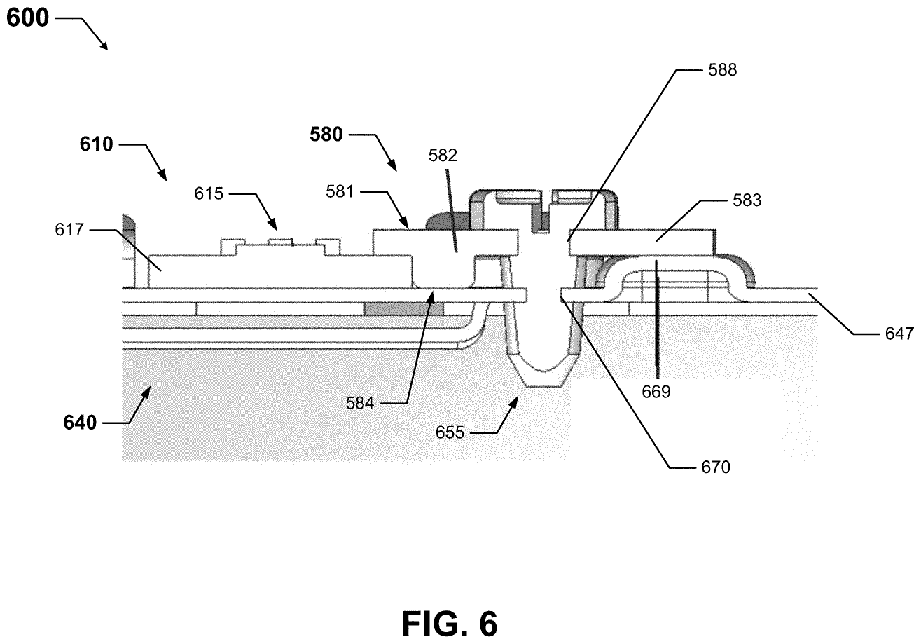

FIG. 6 shows a cross-sectional side view of a portion of an electrical device 600 that includes the fastening device 580 of FIG. 5 in accordance with certain example embodiments. Referring to FIGS. 1 through 6, the electrical device 600 of FIG. 6 is a luminaire includes a circuit board 610 that is substantially the same as the circuit board 110 of FIG. 1. Specifically, the circuit board 610 includes a number of light assemblies 615 disposed on a top surface of the body 617 of the circuit board 610. None of the enclosure coupling features (e.g., enclosure coupling features 218, enclosure coupling features 220) that were previously discussed for the circuit board are shown in FIG. 6 because the location or even the existence of such enclosure coupling features is irrelevant in light of the example fastening devices 680. In this way, example embodiments allow for significantly increased flexibility in terms of where the circuit board 610 can be positioned on the wall 647 of the enclosure 640.

The fastening device 580 is secured to the wall 647 of the enclosure 640 by a coupling device 655 (in this case, a screw). Specifically, the coupling device 655 is disposed in the aperture 588 that traverses the body 581 of the fastening device 580 and also in circuit board coupling feature 670, which is also an aperture in the wall 647. Aperture 588 and the circuit board coupling feature 670 are vertically aligned with each other when the coupling device 655 is inserted.

The protruding section 584 of the fastening device 580 serves as both an alignment mechanism and as a stabilizer that prevents rotation of the fastening device 580. The length 547 of the protruding section 584 abuts entirely against the wall 647 along its bottom and against the side of the body 617 of the circuit board 610 along its distal side surface. In addition, the bottom surface of the distal end of portion 582 of the body 581 abuts against the top surface of the body 617 of the circuit board 610. The height 546 of the protruding section 584 is substantially the same as the thickness of the body 617 of the circuit board 610.

In this way, when the coupling device 655 is engaged with the aperture 588 and the circuit board coupling feature 670, the coupling device 655 is unable to rotate, even if the coupling device 655 becomes loosened over time. To add to the effectiveness of the fastening device 580, portion 583 of the body 581 also becomes engaged with the wall 647. In this example, the circuit board coupling feature 669 (in this case, a dimple) adjacent to the circuit board coupling feature 670 in the wall 647 has a height that is substantially the same as the height 546 of the protruding section 584.

Since portion 582 and portion 583 are planar with each other, this means that the bottom surface of portion 583 of the body 581 abuts against the top surface of the circuit board coupling feature 669 when the coupling device 655 is engaged with the aperture 588 and the circuit board coupling feature 670. If there is no circuit board coupling feature 669, then the fastening device 580 can have an additional protruding section that is disposed to the bottom surface of section 583 of the body 581 to serve the same purpose of stabilizing the fastening device 580.

In certain example embodiments, some or all of the fastening device 580 is made of an electrically non-conductive material to prevent extraneous ground currents, eddy currents, and/or other types of currents that could affect the performance of one or more components (in this case, the light assemblies 615) of the electrical device (in this case, the luminaire 600). Also, the height 545 of the body 581 (or at least portion 582 of the body 581) can be small enough so that the body 581 does not interfere with the light emitted by the light assemblies 615.

This latter feature can be important in applications where tolerances are small. For example, the circuit board 610 of FIG. 6 can have an overall width of approximately one inch, which means that balance must be struck between how small of a fraction of an inch of portion 582 of the body 581 of the fastening device 580 can abut against the top surface of the body 617 of the circuit board 610 and the height 545 of the body 581 of the fastening device 580.

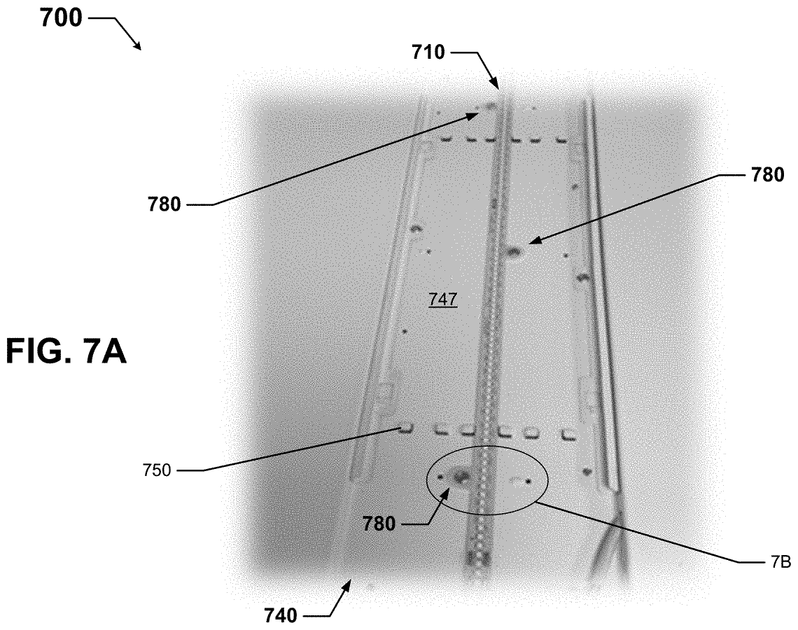

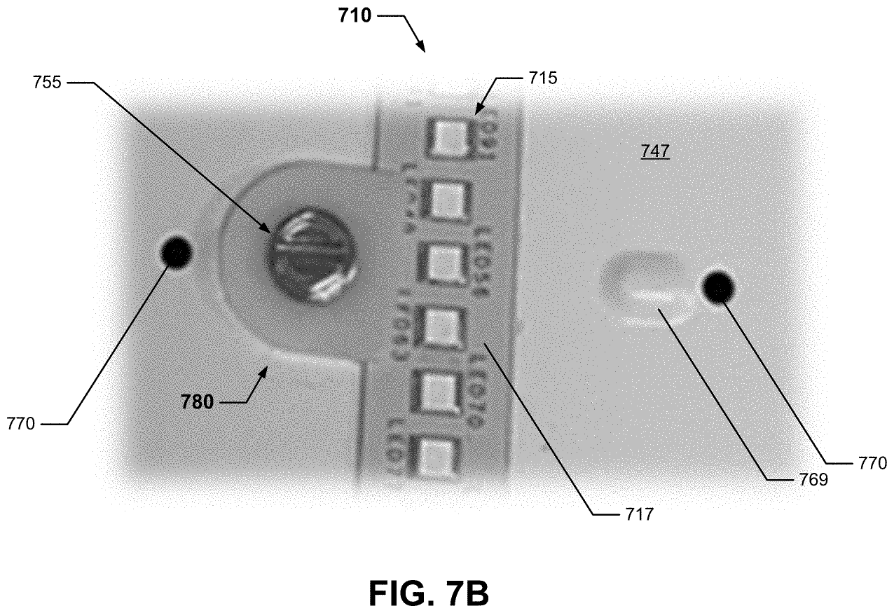

FIGS. 7A and 7B show a portion of another electrical device 700 that includes multiple fastening device 780 in accordance with certain example embodiments. Specifically, FIG. 7A shows a top view of the portion of the electrical device 700, and FIG. 7B shows a detailed view of one of the fastening devices 780. Referring to FIGS. 1 through 7B, the electrical device 700 of FIGS. 7A and 7B is a luminaire includes a circuit board 710 that is substantially the same as the circuit board 110 of FIG. 1. Specifically, the circuit board 710 includes a number of light assemblies 715 disposed on a top surface of the body 717 of the circuit board 710.

The wall 747 of the enclosure 740 includes a number of circuit board coupling features 750, circuit board coupling features 769, and circuit board coupling features 770. The circuit board coupling features 750 are no longer utilized, saving cost and gaining flexibility in terms of how the circuit board 710 can be positioned on the wall 747. While some of circuit board coupling features 769 and circuit board coupling features 770 are used in conjunction with the example fastening devices 780, a user can choose which of these circuit board coupling features 769 and/or circuit board coupling features 770 to utilize based on how the circuit board 710 is to be positioned.

In this example, three fastening devices 780 (approximately on fastening device 780 per foot) are used to secure the circuit board 710 to the wall 747 of the enclosure 740. To help further stabilize the circuit board 710, the fastening devices 780 are alternatively disposed on opposite sides of the circuit board 710. As linear light fixtures such as what is shown in FIGS. 7A and 7B can be quite long, this alternative arrangement is very effective in providing further long-term stability.

FIGS. 8A and 8B show various views of another fastening device 880 in accordance with certain example embodiments. Specifically, FIG. 8A shows a bottom view of the fastening device 880, and FIG. 8B shows a side view of the fastening device 880. Referring to FIGS. 1 through 8B, the example fastening device 880 is substantially the same as the fastening device 580 of FIGS. 5A through 5D, except as described below. In this case, the body 881 has portion 882 and portion 883. Portions 882 and 883 of the body 881 in this case are continuous and planar with respect to each other.

The example fastening device 880 of FIGS. 8A and 8B also includes two protruding sections. In this case, protruding section 884 is disposed on the bottom surface of portion 882 of the body 881, adjacent to the aperture 888. The protruding section 884 in this case includes two protrusions 884-1 and protrusion 884-2 that are circular when viewed from below. The size of protrusion 884-1 and protrusion 884-2 are substantially identical to each other. Protruding section 885 is disposed on the bottom surface of portion 883 of the body 881, adjacent to the aperture 888 in such a manner that protruding section 885, protrusion 884-1, and protrusion 884-2 are substantially the same distance from the center of the aperture 888. The protruding section 885 in this case has a single protrusion that is circular when viewed from below and has a size (e.g., a height) that is substantially similar to the size of protrusions 884-1 and 884-2.

Such a configuration can be used, for example, if a wall of an enclosure lacks a dimple, a protrusion, or some other feature such as circuit board coupling feature 269 of FIG. 2 above. Without such a feature, protruding section 885 can be used as compensation to keep the body 881 substantially parallel to the wall of the enclosure. In such a case, the height of protruding section 884 and protruding section 885 can be substantially the same as the height of the circuit board being secured by the example fastening device 880.

In one or more example embodiments, example embodiments described herein can be used to more efficiently and effectively couple a circuit board to an enclosure of an electrical device. Example embodiments can be used to reduce time of production, reduce materials and labor, and at least maintain reliability of an electrical device. In addition, example embodiments can allow for a flexible arrangement of one or more circuit boards within an enclosure of an electrical device. One or more industry standards that apply to an electrical device can be met using example embodiments described herein.

Accordingly, many modifications and other embodiments set forth herein will come to mind to one skilled in the art to which slide locks for circuit boards pertain having the benefit of the teachings presented in the foregoing descriptions and the associated drawings. Therefore, it is to be understood that slide locks for circuit boards are not to be limited to the specific embodiments disclosed and that modifications and other embodiments are intended to be included within the scope of this application. Although specific terms are employed herein, they are used in a generic and descriptive sense only and not for purposes of limitation.

What is claimed is:

1. A fastening device for a circuit board of an electrical device, wherein the fastening device comprises:
a body comprising a first portion and a second portion, wherein the body has an aperture that traverses threrethrough; and
a first protruding section disposed on a bottom surface of the body adjacent to the aperture,
wherein the first protruding section is configured to abut against a top surface of an enclosure wall of the electrical device and a side of the circuit board,
wherein the aperture is configured to receive a coupling device of the electrical device, and
wherein the first portion of the body is configured to abut against a top surface of the circuit board when the aperture receives the coupling device of the electrical device.

2. The fastening device of claim 1, wherein the aperture is disposed partly in the first portion of the body and partly in the second portion of the body.

3. The fastening device of claim 1, wherein the body and the first protruding section are made of an electrically non-conductive material.

4. The fastening device of claim 1, wherein the first portion and the second portion are planar with respect to each other.

5. The fastening device of claim 4, wherein the second portion abuts against a dimple in the enclosure wall that extends into a cavity of the electrical device.

6. The fastening device of claim 4, further comprising:
a second protruding section disposed on the bottom surface of the second portion of the body adjacent to the aperture, wherein the second protruding section abuts against the top surface of the enclosure wall of the electrical device.

7. The fastening device of claim 1, wherein the first protruding section comprises a single rectangular protrusion.

8. The fastening device of claim 1, wherein the first protruding section comprises a plurality of circular protrusions that are linearly aligned with each other.

9. The fastening device of claim 1, wherein the first portion of the body has a rectangular shape when viewed from above, and wherein the second portion of the body has a semi-circular shape when viewed from above.

10. An electrical device, comprising:
an enclosure comprising:
at least one wall comprising an inner surface; and
a first circuit board coupling feature disposed in the inner surface of the at least one wall, wherein the first circuit board coupling feature comprises a first aperture that traverses the at least one wall;
a circuit board disposed against the inner surface of the at least one wall of the enclosure;
a first fastening device comprising:
a body comprising a first portion and a second portion, wherein the body has a second aperture that traverses therethrough; and
a first protruding section disposed on a bottom surface of the body adjacent to the second aperture; and
a first coupling device that is disposed within the first aperture and the second aperture to secure the first fastening device to the at least one wall of the enclosure,
wherein the first protruding section abuts against the top surface of the at least one wall of the enclosure and a side of the circuit board, and
wherein the first portion of the body abuts against a top surface of the circuit board when the first aperture and the second aperture receive the first coupling device.

11. The electrical device of claim 10, wherein the enclosure is a linear light fixture housing.

12. The electrical device of claim 11, wherein the circuit board comprises a plurality of light sources aligned in at least one row.

13. The electrical device of claim 12, wherein the first portion of the body has a height small enough to avoid interfering with light emitted by the plurality of light sources.

14. The electrical device of claim 12, wherein the first portion of the body and the first protruding section, when abutting against the circuit board, align the first fastening device with respect to the circuit board.

15. The electrical device of claim 14, wherein the first portion of the body and the first protruding section, when abutting against the circuit board, prevent the first fastening device from rotating with respect to the first coupling device over time.

16. The electrical device of claim 10, wherein the enclosure, the circuit board, and the first coupling device are pre-existing relative to the first fastening device.

17. The electrical device of claim 10, further comprising:
a second fastening device identically configured with respect to the first fastening device; and
a second coupling device that is disposed within a third aperture disposed in the at least one wall of the enclosure and the second aperture of the second fastening device to secure the second fastening device to the at least one wall of the enclosure,
wherein a first protruding section of the second fastening device abuts against the top surface of the at least one wall of the enclosure and a side of the circuit board at an additional location relative to the first fastening device, and
wherein a first portion of the body of the second fastening device abuts against the top surface of the circuit board at the additional location when the first aperture and the second aperture of the second fastening device receive the second coupling device.

18. The electrical device of claim 17, wherein the additional location is on an opposite side of circuit board.

19. The electrical device of claim 10, wherein the at least one first circuit board coupling feature further comprises a dimple protruding from the at least one wall adjacent to the first aperture, wherein the second portion of the body of the first fastening device abuts against the dimple when the first aperture and the second aperture receive the first coupling device.

20. The electrical device of claim 10, wherein the first protruding section extends from the bottom surface of the first portion of the body.
